(19) United States
(12) Patent Application Publication
(10) Pub. No.: US 2026/0150688 A1
(43) Pub. Date: May 28, 2026

(54) SEMICONDUCTOR PACKAGE

(71) Applicant: Samsung Electronics Co., Ltd., Suwon-si (KR)

(72) Inventors: Haemin PARK, Suwon-si (KR); Junyun KWEON, Suwon-si (KR); Wooju KIM, Suwon-si (KR); Je-Sung KIM, Suwon-si (KR); Taeduk NAM, Suwon-si (KR); Kangil YUN, Suwon-si (KR); Junho YOON, Suwon-si (KR); Kwang Yong LEE, Suwon-si (KR); Dayoung CHO, Suwon-si (KR); Jinwook HONG, Suwon-si (KR)

(73) Assignee: Samsung Electronics Co., Ltd., Suwon-si (KR)

(21) Appl. No.: 19/257,039

(22) Filed: Jul. 1, 2025

(30) Foreign Application Priority Data
Nov. 26, 2024 (KR) 10-2024-0171017

(51) Int. Cl. H01L 23/00; H01L 23/498; H01L 23/544

(52) U.S. Cl. CPC H10W 42/121; H10W 46/00; H10W 46/503; H10W 90/701; H10W 90/724

(57) ABSTRACT

Provided is a semiconductor package comprising a semiconductor substrate comprising a device region on an upper surface of the semiconductor substrate, and a dummy region surrounding the device region, an integrated circuit on the upper surface of the semiconductor substrate in the device region, a first interlayer insulating layer covering the integrated circuit on the upper surface of the semiconductor substrate, a second interlayer insulating layer on the first interlayer insulating layer, a dielectric layer between the first interlayer insulating layer and the second interlayer insulating layer, a trench vertically penetrating the second interlayer insulating layer and the dielectric layer in the dummy region, and a passivation layer on the second interlayer insulating layer. The trench surrounds the device region along the dummy region.

### CROSS-REFERENCE TO RELATED APPLICATIONS

This U.S. non-provisional patent application claims priority under 35 U.S.C. § 119 of Korean Patent Application No. 10-2024-0171017, filed on Nov. 26, 2024, the entire contents of which are hereby incorporated by reference.

### BACKGROUND

Example embodiments of the present disclosure herein relate to a semiconductor package and a method for manufacturing the same, and particularly, to a semiconductor package including a semiconductor chip formed on a semiconductor substrate, and a method for manufacturing the semiconductor package.

Semiconductor packages may be manufactured by preparing one or more integrated circuit chips into a form suitable for use in electronic products. In general, semiconductor packages may be manufactured by mounting one or more semiconductor chips on a substrate such as a printed circuit board (PCB) and electrically connecting them using bonding wires or bumps.

In a process of manufacturing semiconductor chips, a plurality of semiconductor chips may be manufactured on a single wafer. Typically, the semiconductor chips may form integrated circuits and wires on a semiconductor substrate, such as a semiconductor wafer, and then a sawing process may be performed to separate the semiconductor chips on the semiconductor substrate from each other.

### SUMMARY

Some example embodiments of the present disclosure provide a semiconductor package with improved structural stability and/or reliability.

Some example embodiments of the present disclosure also provide a method for manufacturing a semiconductor package with reduced process defects.

Some example embodiments of the inventive concepts provide a semiconductor substrate comprising a device region on an upper surface of the semiconductor substrate, and a dummy region surrounding the device region, an integrated circuit on the upper surface of the semiconductor substrate in the device region, a first interlayer insulating layer covering the integrated circuit on the upper surface of the semiconductor substrate, a second interlayer insulating layer on the first interlayer insulating layer, a dielectric layer between the first interlayer insulating layer and the second interlayer insulating layer, a trench vertically penetrating the second interlayer insulating layer and the dielectric layer in the dummy region, and a passivation layer on the second interlayer insulating layer. The trench surrounds the device region along the dummy region.

In some example embodiments of the inventive concepts, a semiconductor package comprises a semiconductor substrate comprising a device region on an upper surface of the semiconductor substrate, and a dummy region surrounding the device region, an integrated circuit on the upper surface of the semiconductor substrate in the device region, a first interlayer insulating layer covering the integrated circuit on the upper surface of the semiconductor substrate, a second interlayer insulating layer on the first interlayer insulating layer, a dielectric layer between the first interlayer insulating layer and the second interlayer insulating layer, a trench vertically penetrating the second interlayer insulating layer and the dielectric layer in the dummy region, and a passivation layer on the second interlayer insulating layer. The first interlayer insulating layer comprises a first part adjacent to the trench, and a second part spaced apart from the trench by the first part, the first part and the second part are composed of a same material, the first part has an amorphous structure, and the second part has a crystalline structure.

In some example embodiments of the inventive concepts, a semiconductor package comprises a package substrate, and a semiconductor chip mounted on the package substrate. The semiconductor chip comprises a semiconductor substrate comprising a device region on an upper surface of the semiconductor substrate, and a dummy region surrounding the device region, an integrated circuit on the upper surface of the semiconductor substrate in the device region, a first interlayer insulating layer covering the integrated circuit on the upper surface of the semiconductor substrate, a second interlayer insulating layer on the first interlayer insulating layer, a dielectric layer between the first interlayer insulating layer and the second interlayer insulating layer, a passivation layer on the second interlayer insulating layer, an align key provided onto the semiconductor substrate in the dummy region, and a trench vertically penetrating the passivation layer, the second interlayer insulating layer and the dielectric layer in the dummy region, the align key is between a lower surface of the first interlayer insulating layer and an upper surface of the second interlayer insulating layer, a lowermost end of the trench is at a level lower than an upper surface of the first interlayer insulating layer, the trench, at least partially, vertically penetrates the align key, and the trench horizontally crosses the align key.

In some example embodiments of the inventive concepts, a method of manufacturing a semiconductor package comprises forming a plurality of semiconductor chips on a semiconductor substrate, the semiconductor substrate comprising a plurality of device regions, and scribe lane region therebetween, forming a first interlayer insulating layer and a first wiring pattern on the semiconductor substrate, the first interlayer insulating layer covering the plurality of device regions and the scribe lane region, forming a dielectric layer on the first interlayer insulating layer, forming a second interlayer insulating layer and a second wiring pattern on the dielectric layer, forming a passivation layer on the second interlayer insulating layer and the first wiring pattern, the second interlayer insulating layer covering the plurality of device regions and the scribe lane region, and forming a trench penetrating the passivation layer, the second interlayer insulating layer, the second wiring pattern, the dielectric layer, the first wiring pattern, and at least a portion of the first interlayer insulating layer in the scribe lane region.

In some example embodiments of the inventive concepts, a method of manufacturing a semiconductor package further comprises, in the forming of the first wiring pattern, an align key is formed in the first interlayer insulating layer in the scribe lane region.

### BRIEF DESCRIPTION

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

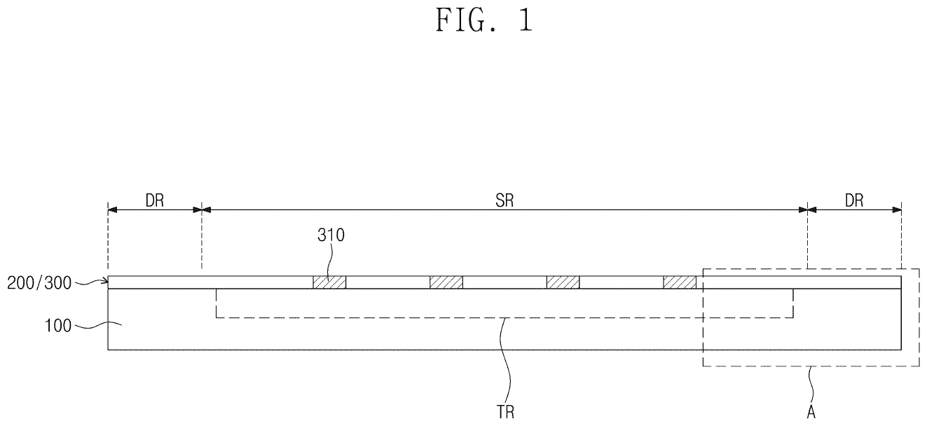

FIG. 1 is a cross-sectional view for describing a semiconductor package according to some example embodiments of the inventive concepts;

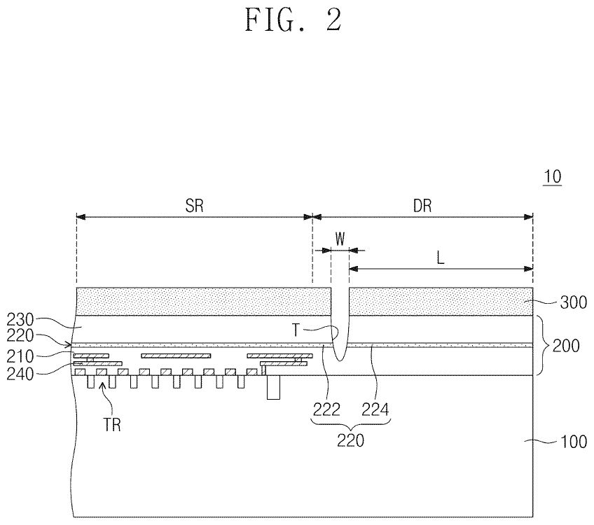

FIG. 2 is an enlarged view illustrating some region of a semiconductor package according to some example embodiments of the inventive concepts;

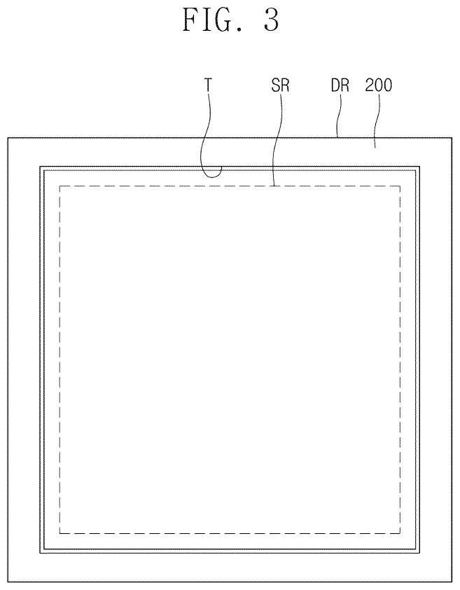

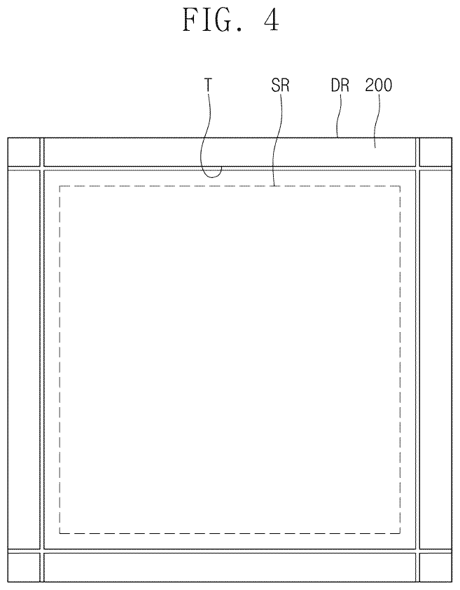

FIGS. 3 and 4 are plan views for describing a semiconductor package according to some example embodiments of the inventive concepts;

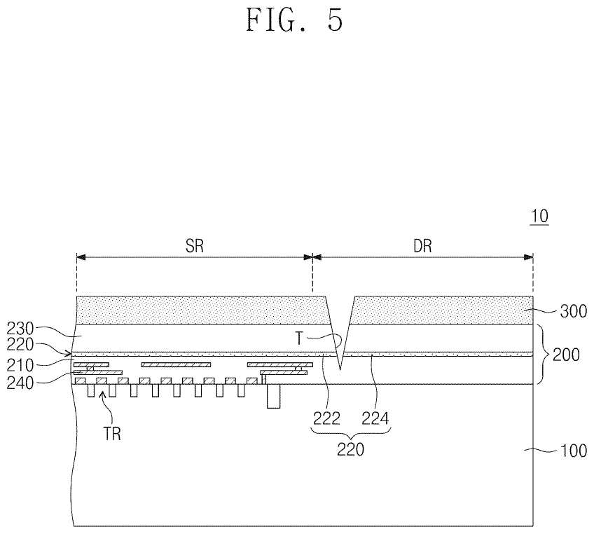

FIGS. 5 to 10 are enlarged views illustrating some regions of a semiconductor package according to some example embodiments of the inventive concepts;

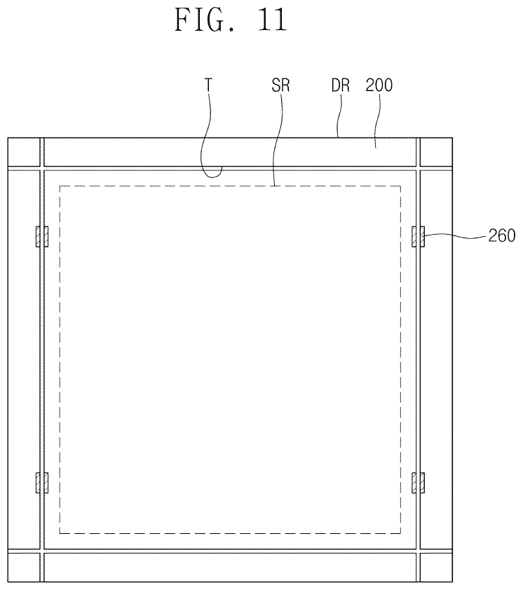

FIG. 11 is a plan view for describing a semiconductor package according to some example embodiments of the inventive concepts;

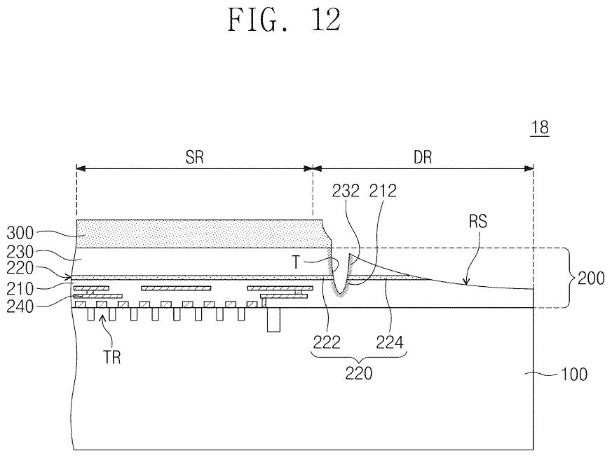

FIG. 12 is an enlarged view illustrating some region of a semiconductor package according to some example embodiments of the inventive concepts;

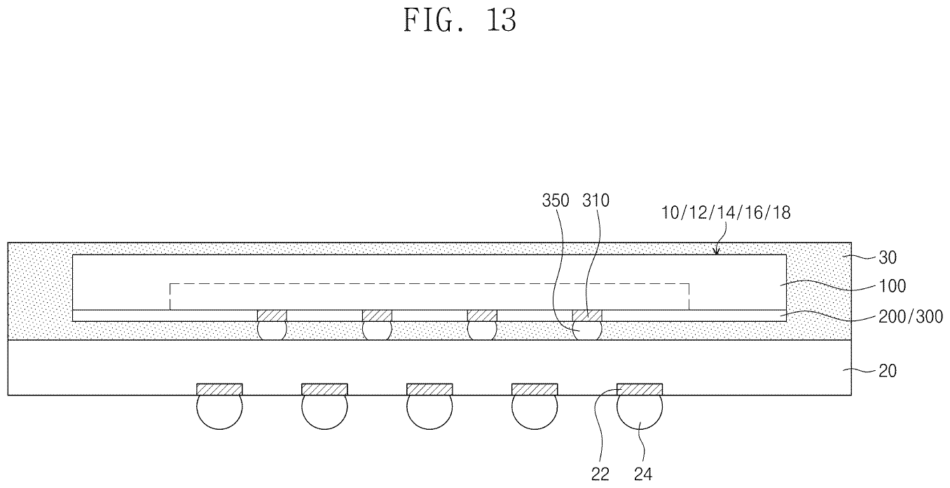

FIG. 13 is a cross-sectional view for describing a semiconductor package according to some example embodiments of the inventive concepts; and

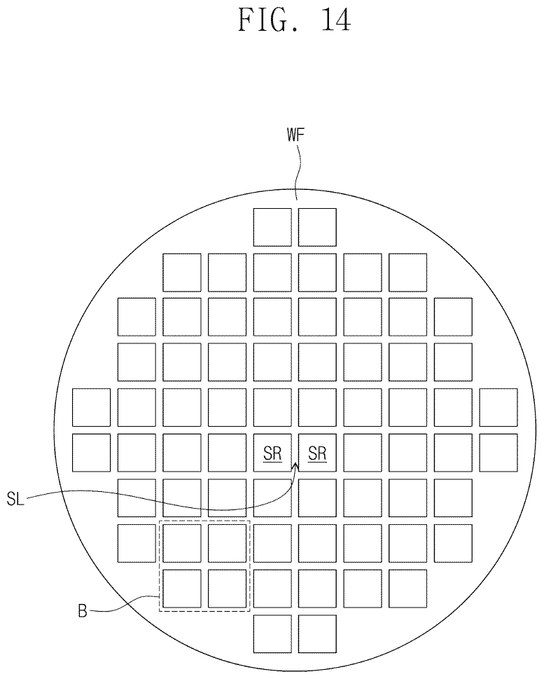

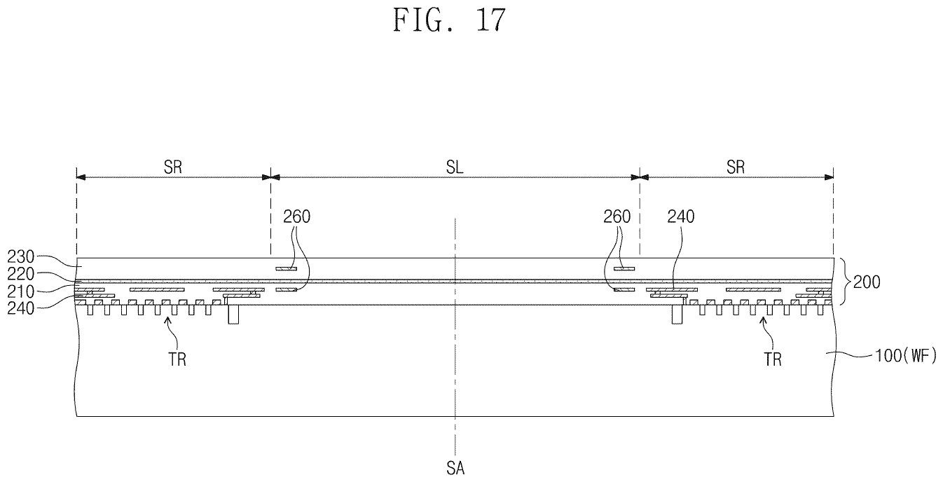

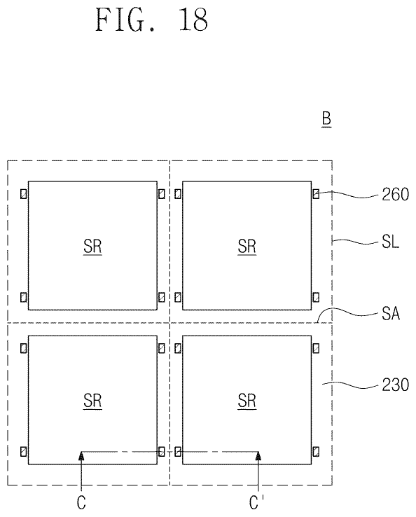

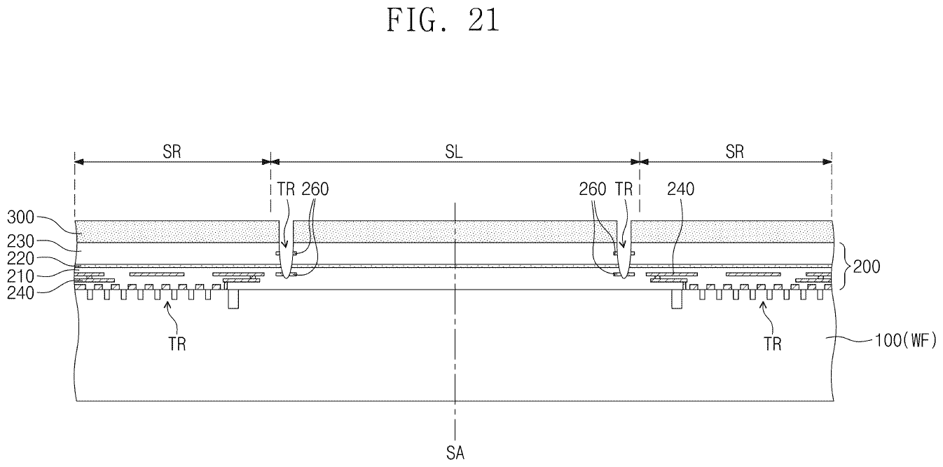

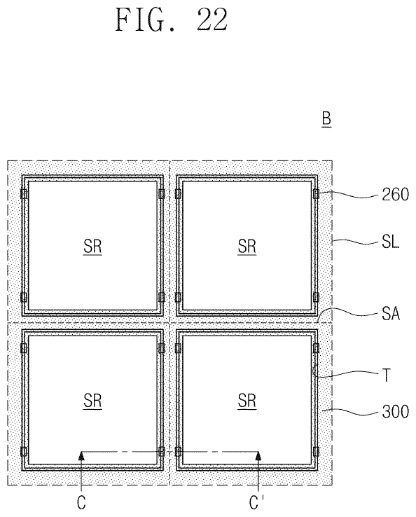

FIGS. 14 to 24 are cross-sectional and plan views for describing a method for manufacturing a semiconductor package according to some example embodiments of the inventive concepts.

### DETAILED DESCRIPTION

A semiconductor package according to some example embodiments of the inventive concepts will be described with reference to the drawings.

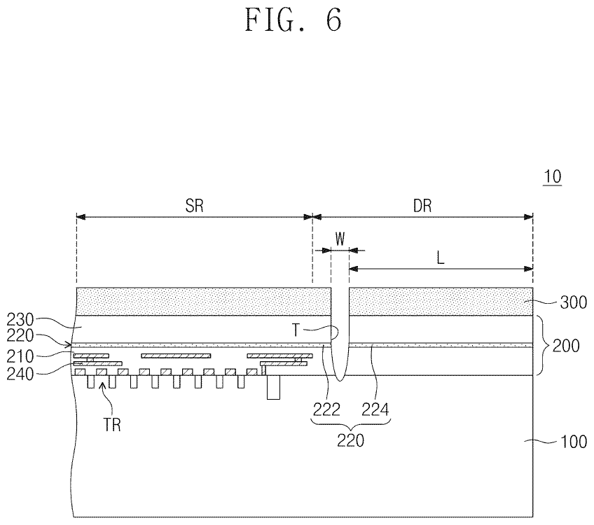

FIG. 1 is a cross-sectional view for describing the semiconductor package according to some example embodiments of the inventive concepts. FIG. 2 is an enlarged view illustrating some region of the semiconductor package according to some example embodiments of the inventive concepts. FIGS. 3 and 4 are plan views for describing the semiconductor package according to some example embodiments of the inventive concepts. FIGS. 5 and 6 are enlarged views illustrating some regions of the semiconductor package according to some example embodiments of the inventive concepts. FIGS. 2 and 5 correspond to region A of FIG. 1.

Referring to FIGS. 1 and 2, the semiconductor package may include a semiconductor chip 10.

The semiconductor chip 10 may include a semiconductor substrate 100, a wiring layer 200, and a passivation layer 300.

The semiconductor substrate 100 may include a semiconductor material. For example, the semiconductor substrate 100 may be a silicon (Si), silicon carbide (SiC), silicon germanium (SiGe), or gallium nitride (GaN) substrate or a combination thereof. However, example embodiments are not limited thereto.

An upper surface of the semiconductor substrate 100 may have a device region SR and a dummy region DR. The device region SR may be located on the center of the upper surface of the semiconductor substrate 100. The dummy region DR may be located on an edge of the upper surface of the semiconductor substrate 100. In a plan view, the dummy region DR may surround the device region SR. The device region SR may be spaced apart from side surfaces of the semiconductor substrate 100 by the dummy region DR. The device region SR may be a region on which an integrated circuit of the semiconductor chip 10 is provided. The dummy region DR may be a remaining region on which the integrated circuit is not provided. The dummy region DR may be a buffer region for limiting and/or preventing the integrated circuit from being damaged in a process of manufacturing the semiconductor package, particularly, a process of cutting the semiconductor substrate 100.

The integrated circuit may be provided on the upper surface of the semiconductor substrate 100. The integrated circuit may be provided on the device region SR of the semiconductor substrate 100. The integrated circuit may not be provided in the dummy region DR of the semiconductor substrate 100. For example, a plurality of transistors TR may be disposed on the semiconductor substrate 100. More specifically, the transistors TR may be formed on the upper surface of the semiconductor substrate 100 on the device region SR. For example, the semiconductor chip 10 may be a logic chip, a memory chip, power semiconductor, sensor device, etc. the transistors TR may constitute a logic circuit, a memory circuit, power semiconductor circuit, sensor circuit, etc. However, example embodiments are not limited thereto.

The wiring layer 200 may be provided on the semiconductor substrate 100. The wiring layer 200 may include a first interlayer insulating layer 210, a dielectric layer 220 and a second interlayer insulating layer 230 stacked on the semiconductor substrate 100. The wiring layer 200 may include wiring patterns 240 provided in the first interlayer insulating layer 210 and the second interlayer insulating layer 230.

The first interlayer insulating layer 210 may be disposed on the semiconductor substrate 100. The first interlayer insulating layer 210 may cover the upper surface of the semiconductor substrate 100. The first interlayer insulating layer 210 may cover the device region SR and the dummy region DR. The first interlayer insulating layer 210 may cover the transistors TR on the upper surface of the semiconductor substrate 100. The first interlayer insulating layer 210 may include an insulating material. For example, the first interlayer insulating layer 210 may include one of high-density plasma (HDP) oxide, undoped silicate glass (USG), tetraethyl orthosilicate (TEOS), silicon nitride (SiN), silicon oxide (SiO), silicon oxycarbide (SiOC), silicon oxynitride (SiON) and silicon carbonitride (SiCN). However, example embodiments are not limited thereto. The first interlayer insulating layer 210 may have a single-layered or multi-layered structure.

The dielectric layer 220 may be disposed on the first interlayer insulating layer 210. The dielectric layer 220 may cover an upper surface of the first interlayer insulating layer 210. The dielectric layer 220 may cover the device region SR and the dummy region DR. The dielectric layer 220 may include a dielectric material. For example, the dielectric layer 220 may include one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, and aluminum oxide. However, example embodiments are not limited thereto. The dielectric layer 220 may have a single-layered or multi-layered structure.

The second interlayer insulating layer 230 may be disposed on the dielectric layer 220. The second interlayer insulating layer 230 may cover an upper surface of the dielectric layer 220. The second interlayer insulating layer 230 may cover the device region SR and the dummy region DR. The second interlayer insulating layer 230 may include an insulating material. For example, the second interlayer insulating layer 230 may include one of high-density plasma (HDP) oxide, undoped silicate glass (USG), tetraethyl orthosilicate (TEOS), silicon nitride (SiN), silicon oxide (SiO), silicon oxycarbide (SiOC), silicon oxynitride (SiON) and silicon carbonitride (SiCN). However, example embodiments are not limited thereto. The second interlayer insulating layer 230 may have a single-layered or multi-layered structure.

The wiring patterns 240 connected to the transistors TR may be provided in the wiring layer 200 on the device region SR. The wiring patterns 240 may include signal wiring patterns buried in the first interlayer insulating layer 210 and the second interlayer insulating layer 230. For example, the signal wiring patterns may include redistribution patterns for horizontal wiring and via patterns for vertical connections. It is illustrated in FIG. 2 that the wiring patterns 240 are provided only in the first interlayer insulating layer 210, but FIG. 2 illustrates only some of the wiring patterns 240, and the inventive concepts are not limited thereto. The wiring patterns 240 may be also provided in the second interlayer insulating layer 230. The wiring patterns 240 may vertically penetrate the first interlayer insulating layer 210 to be connected to any one of a source electrode, a drain electrode, or a gate electrode of the transistors TR. Alternatively, the wiring patterns 240 may be connected to various devices of the semiconductor chip 10. Although not shown in FIG. 2, the wiring patterns 240 may include vertical wires vertically penetrating the dielectric layer 220 to connect the wiring patterns 240 in the first interlayer insulating layer 210 and wiring patterns in the second interlayer insulating layer 230. The wiring patterns 240 may be located between an upper surface and a lower surface of the wiring layer 200. The wiring patterns 240 may not be located in the dummy region DR. The wiring patterns 240 may include a conductive material. For example, the wiring patterns 240 may include a metal material such as aluminum (Al), copper (Cu), or tungsten (W). However, example embodiments are not limited thereto.

The passivation layer 300 may be disposed on the wiring layer 200. The passivation layer 300 may cover an upper surface of the second interlayer insulating layer 230. The passivation layer 300 may cover the device region SR and the dummy region DR. In other words, the passivation layer 300 may partially vertically penetrate the dielectric layer 220 and the second interlayer insulating layer 230 in the dummy region DR.

The semiconductor chip 10 may have a trench T. Hereinafter, referring to FIG. 3, the trench T will be described in more detail.

Referring to FIGS. 1 to 3, the trench T may be located in the dummy region DR. The trench T may surround the device region SR along the dummy region DR. In a plan view, the trench T may have a form of a closed shape surrounding the device region SR. In the present specification, the closed shape may mean a shape of a loop having a closed form, that is, a shape of a ring having various forms. That is, the closed shape is not limited to a shape of the ring including a curve. For example, a planar shape of the trench T may have a shape of a tetragonal ring, a circular ring, a polygonal ring, or a ring having various forms. The trench T may be horizontally spaced apart from the device region SR. More preferably, the trench T may be horizontally spaced apart from the transistors TR. The trench T may be spaced apart from the side surfaces of the semiconductor substrate 100. In other words, the trench T may be located between the device region SR and the side surfaces of the semiconductor substrate 100). A distance L is a distance in which the trench T is spaced apart from the side surfaces of the semiconductor substrate 100, and may be about 3 μm to about 20 μm.

According to some example embodiments, as illustrated in FIG. 4, in a plan view, the trench T may have a lattice shape. In other words, the trench T may have a #shape). In this case, the trench T may surround the device region SR. For example, the device region SR may be located inside one lattice or #constituted by the trench T. In other words, in a plan view, the trench T may have a form of a tetragonal closed shape surrounding the device region SR, but each side of the closed shape may extend to side surfaces of the semiconductor package. Alternatively, the trench T may have a configuration in which four sub-trenches surrounding the device region are connected, but each of the sub-trenches may completely cross the semiconductor chip 10 in a horizontal direction. Hereinafter, descriptions will be made in reference to some example embodiments of FIG. 3.

The trench T may face an inside of the wiring layer 200 from an upper surface of the passivation layer 300. The trench T may vertically penetrate the passivation layer 300, the second interlayer insulating layer 230 and the dielectric layer 220. The trench T may partially vertically penetrate the first interlayer insulating layer 210. In other words, the trench T may extend from the upper surface of the passivation layer 300 toward an inside of the first interlayer insulating layer 210. A lowermost end of the trench T may be located between the upper surface of the first interlayer insulating layer 210 and a lower surface of the first interlayer insulating layer 210. The trench T may have a cross-sectional shape of U shape. Alternatively, as illustrated in FIG. 5, the trench T may have a cross-sectional shape of V shape, but the inventive concepts are not limited thereto, and the trench T may have a cross-sectional shape of a tetragon or various forms. The trench T may have a width W of about 3 μm to about 20 μm. Here, the width W of the trench T may mean the greatest width of the trench T. For example, the width W of the trench T may correspond to a width of an uppermost end of the trench T, that is, a width measured on the upper surface of the second interlayer insulating layer 230.

According to some example embodiments, as illustrated in FIG. 6, the trench T may face the inside of the semiconductor substrate 100 from the upper surface of the passivation layer 300. The trench T may vertically penetrate the passivation layer 300, the second interlayer insulating layer 230, the dielectric layer 220 and the first interlayer insulating layer 210. The trench T may partially vertically penetrate the semiconductor substrate 100. In other words, the trench T may extend from the upper surface of the passivation layer 300 toward the inside of the semiconductor substrate 100. The lowermost end of the trench T may be located at a level lower than the upper surface of the semiconductor substrate 100. Hereinafter, descriptions will be made in reference to some example embodiments of FIG. 3.

Since the trench T vertically penetrates the dielectric layer 220, the dielectric layer 220 may have a first dielectric layer 222 and a second dielectric layer 224 separated from each other by the trench T. The first dielectric layer 222 may be located on the device region SR. The first dielectric layer 222 may partially extend onto the dummy region DR. In this case, the first dielectric layer 222 may be partially located between the device region SR and the trench T. The first dielectric layer 222 may be in contact with one inner side surface of the trench T facing the device region SR. The second dielectric layer 224 may be located in the dummy region DR. The second dielectric layer 224 may be located between the side surfaces of the semiconductor substrate 100 and the trench T. The second dielectric layer 224 may be in contact with another inner side surface of the trench T facing the side surfaces of the semiconductor substrate 100. The first dielectric layer 222 and the second dielectric layer 224 may be located at the same vertical level. For example, an upper surface of the first dielectric layer 222 and an upper surface of the second dielectric layer 224 may be located at the same vertical level, and a lower surface of the first dielectric layer 222 and a lower surface of the second dielectric layer 224 may be located at the same vertical level. In other words, the first dielectric layer 222 and the second dielectric layer 224 may be layers separated from one material layer.

The dielectric layer 220 including a dielectric material may have a lower hardness than the first interlayer insulating layer 210 and the second interlayer insulating layer 230. Accordingly, the dielectric layer 220 may be easily damaged by an external impact or contraction or expansion of the semiconductor chip 10. For example, damage such as a crack, or the like may occur in the dielectric layer 220, and the crack may propagate to an inner side of the semiconductor chip 10 along the upper surface, a lower surface or an inside of the dielectric layer 220.

According to some example embodiments of the inventive concepts, since the trench T separating the dielectric layer 220 into the first dielectric layer 222 and the second dielectric layer 224 is provided in the dummy region DR located outside the device region SR, the damage such as the crack may not propagate from an outside of the semiconductor chip 10 toward the device region SR. That is, the semiconductor package with improved structural stability and/or reliability may be provided. In addition, since the trench T is provided so as to entirely surround the device region SR, the second dielectric layer 224 located outside the semiconductor chip 10 may be separated from the first dielectric layer 222 located on the device region SR without a connection part therebetween. That is, the trench T may suppress the damage or a fracture from propagating from the outside of the semiconductor chip 10 toward the device region SR, and the semiconductor package with more improved structural stability and/or reliability may be provided.

Referring back to FIGS. 1 and 2, the semiconductor chip 10 may include chip pads 310 disposed adjacent to an upper surface of the semiconductor chip 10. The chip pads 310 may be provided in the passivation layer 300. The chip pads 310 may be exposed onto the upper surface of the passivation layer 300. Upper surfaces of the chip pads 310 may be coplanar (and/or substantially coplanar) with the upper surface of the passivation layer 300. However, the inventive concepts are not limited thereto, and the chip pads 310 may protrude onto the upper surface of the passivation layer 300. The chip pads 310 may be exposed onto a lower surface of the passivation layer 300. The chip pads 310 may be connected to the wiring patterns 240 provided in the second interlayer insulating layer 230. The chip pads 310 may be electrically connected to the transistors TR formed on the semiconductor substrate 100 through the wiring patterns 240. The chip pads 310 may be composed of metal such as copper (Cu).

In some example embodiments below, for convenience of description, duplicate specific description, for technical features, of that made above with reference to FIGS. 1 to 6 will be omitted, and a difference will be described in detail. The same reference numerals and symbols may be provided to the same components as those of the semiconductor package according to some example embodiments of the inventive concepts described above.

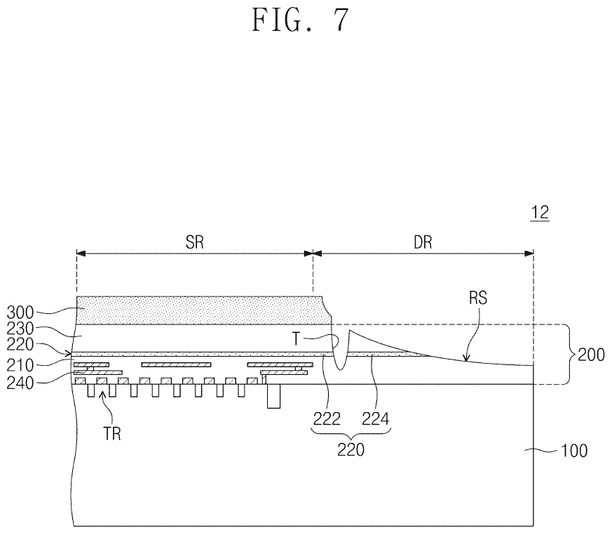

FIG. 7 is an enlarged view illustrating some region of the semiconductor package according to some example embodiments of the inventive concepts.

Referring to FIG. 7, the semiconductor package may include a semiconductor chip 12.

The semiconductor chip 12 may have a recess region RS. The recess region RS may be located in the dummy region DR. The recess region RS may surround the device region SR along the dummy region DR. The recess region RS may be horizontally spaced apart from the device region SR. The recess region RS may be spaced apart from the side surfaces of the semiconductor substrate 100. In other words, the recess region RS may be located between the device region SR and the side surfaces of the semiconductor substrate 100.

The recess region RS may face the inside of the wiring layer 200 from the upper surface of the passivation layer 300. The recess region RS may penetrate the passivation layer 300, the second interlayer insulating layer 230 and the dielectric layer 220. The recess region RS may partially vertically penetrate the first interlayer insulating layer 210. In other words, a bottom surface of the recess region RS may expose the first interlayer insulating layer 210. One surface of the first interlayer insulating layer 210 exposed onto the bottom surface of the recess region RS may be in contact with the side surfaces of the semiconductor substrate 100. A lowermost end of the recess region RS may be in contact with the side surfaces of the semiconductor substrate 100. Alternatively, the lowermost end of the recess region RS may be adjacent to the side surfaces of the semiconductor substrate 100. In this case, the lowermost end of the recess region RS may be located between the side surfaces of the semiconductor substrate 100 and the trench T.

The recess region RS may extend onto the trench T. In a plan view, the trench T may be located inside the recess region RS. In this case, the trench T may be exposed onto the bottom surface of the recess region RS. However, the inventive concepts are not limited thereto, and the recess region RS may be located between the trench T and the side surfaces of the semiconductor substrate 100. FIG. 7 illustrates that the bottom surface of the recess region RS is a concave surface, but the inventive concepts are not limited thereto.

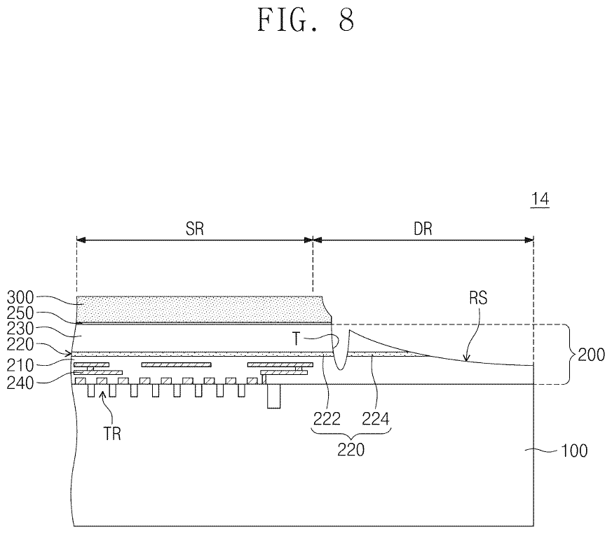

FIG. 8 is an enlarged view illustrating some region of the semiconductor package according to some example embodiments of the inventive concepts.

Referring to FIG. 8, the semiconductor package may include a semiconductor chip 14.

Compared with the semiconductor chip 10 described with reference to FIG. 2, the semiconductor chip 14 may further include an additional insulating layer 250. The additional insulating layer 250 may be interposed between the wiring layer 200 and the passivation layer 300. More specifically, the additional insulating layer 250 may be interposed between the second interlayer insulating layer 230 and the passivation layer 300. The additional insulating layer 250 may conformally cover the upper surface of the second interlayer insulating layer 230. The additional insulating layer 250 may be exposed onto an inner wall of the trench T. As illustrated in FIG. 7, when the semiconductor chip 14 has the recess region RS, the additional insulating layer 250 may not extend onto the bottom surface of the recess region RS. The additional insulating layer 250 may include an insulating material. The additional insulating layer 250 may include a material different from the second interlayer insulating layer 230. For example, when the second interlayer insulating layer 230 includes silicon oxide, or tetraethyl orthosilicate, the additional insulating layer 250 may include silicon nitride (SiN). However, example embodiments are not limited thereto.

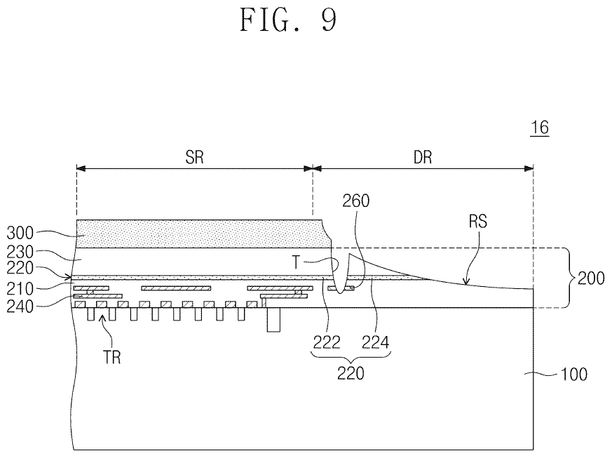

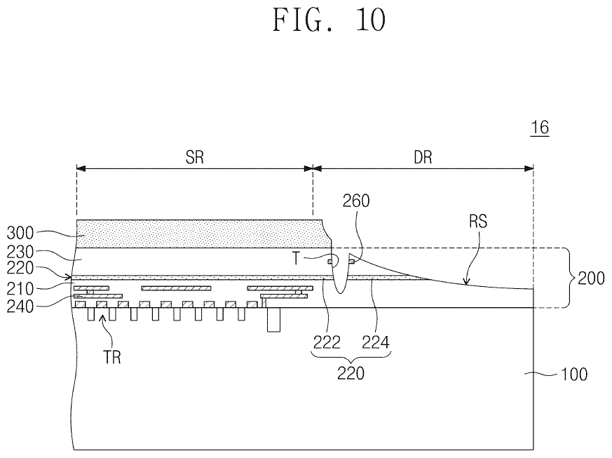

FIGS. 9 and 10 are enlarged views illustrating some region of the semiconductor package according to some example embodiments of the inventive concepts. FIG. 11 is a plan view for describing the semiconductor package according to some example embodiments of the inventive concepts.

Referring to FIG. 9, the semiconductor package may include a semiconductor chip 16.

Compared with the semiconductor chip 10 described with reference to FIG. 2, the semiconductor chip 16 may further include an align key 260. The align key 260 may be an align key used for disposition and aligning of components in the semiconductor chip 16, particularly components such as the wiring patterns 240 in the wiring layer 200, in a process of manufacturing the semiconductor package. The align key 260 may be located between the lower surface of the first interlayer insulating layer 210 and the upper surface of the second interlayer insulating layer 230.

As illustrated in FIG. 9, the align key 260 may be provided in the first interlayer insulating layer 210. According to other embodiments, as illustrated in FIG. 10, the align key 260 may be provided in the second interlayer insulating layer 230. Alternatively, the align key 260 may be provided in plurality, and may be provided in each of the first interlayer insulating layer 210 and the second interlayer insulating layer 230.

The align key 260 may be located at the same vertical level as any one of the wiring patterns 240. The align key 260 may include the same material as the wiring patterns 240. In other words, the wiring patterns 240 and the align key 260 may be components formed by patterning one material layer, for example, a metal layer. The align key 260 may include a conductive material. For example, the align key 260 may include a metal material such as copper (Cu) or tungsten (W). However, example embodiments are not limited thereto. Alternatively, the align key 260 may include a material different from the wiring patterns 240. The align key 260 may be located at a vertical level different from the wiring patterns 240.

Referring to FIGS. 9 to 11 together, the align key 260 may be located in the dummy region DR. In a plan view, the trench T may cross the align key 260. The trench T may vertically penetrate the align key 260. In other words, the align key 260 may be separated into two parts by the trench T. Each part of the align key 260 may be exposed onto the inner wall of the trench T.

FIG. 12 is an enlarged view illustrating some region of the semiconductor package according to some example embodiments of the inventive concepts.

Referring to FIG. 12, the first interlayer insulating layer 210 may include a first adjacent part 212 adjacent to the trench T. A remaining part of the first interlayer insulating layer 210 except for the first adjacent part 212 may be spaced apart from the trench T by the first adjacent part 212. That is, the first adjacent part 212 may be a part in contact with the trench T in the first interlayer insulating layer 210. The remaining part of the first interlayer insulating layer 210 and the first adjacent part 212 may include the same material as each other. For example, the remaining part of the first interlayer insulating layer 210 and the first adjacent part 212 may include silicon oxide. The remaining part of the first interlayer insulating layer 210 may have a greater crystallinity than the first adjacent part 212. For example, the remaining part of the first interlayer insulating layer 210 may have a greater crystalline grain size than the first adjacent part 212. For example, the remaining part of the first interlayer insulating layer 210 may have a crystalline structure, and the first adjacent part 212 may have an amorphous structure.

The second interlayer insulating layer 230 may include a second adjacent part 232 adjacent to the trench T. A remaining part of the second interlayer insulating layer 230 except for the second adjacent part 232 may be spaced apart from the trench T by the second adjacent part 232. That is, the second adjacent part 232 may be a part in contact with the trench T in the second interlayer insulating layer 230. The remaining part of the second interlayer insulating layer 230 and the second adjacent part 232 may have the same material as each other. For example, the remaining part of the second interlayer insulating layer 230 and the second adjacent part 232 may include silicon oxide. The remaining part of the second interlayer insulating layer 230 may have a greater crystallinity than the second adjacent part 232. For example, the remaining part of the second interlayer insulating layer 230 may have a greater crystalline grain size than the second adjacent part 232. For example, the remaining part of the second interlayer insulating layer 230 may have a crystalline structure, and the second adjacent part 232 may have an amorphous structure.

The first adjacent part 212 may be in contact with the lower surface of the dielectric layer 220. The second adjacent part 232 may be in contact with the upper surface of the dielectric layer 220.

According to some example embodiments of the inventive concepts, the first interlayer insulating layer 210 and the second interlayer insulating layer 230 may be provided as a structure in which parts thereof in contact with the trench T are amorphous. The first adjacent part 212 and the second adjacent part 232 provided as amorphous structures may be more crack-resistant than the remaining part of the first interlayer insulating layer 210 and the remaining part of the second interlayer insulating layer 230. That is, the semiconductor package with improved structural stability and/or reliability may be provided.

FIG. 13 is a cross-sectional view for describing the semiconductor package according to some example embodiments of the inventive concepts.

Referring to FIG. 13, a package substrate 20 may be provided. The package substrate 20 may be a printed circuit board (PCB) having a signal pattern provided on an upper surface of the package substrate 20. The package substrate 20 may have a structure having a core pattern and wiring layers stacked on each of an upper surface and a lower surface of the core pattern.

According to some example embodiments, the package substrate 20 may be a redistribution substrate. For example, the package substrate 20 may include at least two substrate wiring layers mutually stacked. In the present specification, the substrate wiring layer may mean a wiring layer formed by patterning each of one insulating material layer and one conductive material layer. That is, conductive patterns in one substrate wiring layer may be horizontally extending wires, and may not vertically overlap each other. Each of the substrate wiring layers may include substrate insulating patterns and substrate wiring patterns in the substrate insulating patterns. The substrate wiring patterns of any one substrate wiring layer may be electrically connected to the substrate wiring patterns of another adjacent substrate wiring layer.

The package substrate 20 may include upper substrate pads for connecting a semiconductor chip 10, 12, 14, 16 or 18 to be described later to the package substrate 20. The package substrate 20 may include lower substrate pads 22 provided on a lower surface of the package substrate 20.

External terminals 24 may be provided on the lower surface of the package substrate 20. The external terminals 24 may be disposed on the lower substrate pads 22. The external terminals 24 may include a solder ball, solder bump or solder pad. The package substrate 20 may include a ball grid array (BGA), fine ball grid array (FBGA) or land grid array (LGA) depending on types of the external terminals 24.

The semiconductor chip 10, 12, 14, 16 or 18 may be disposed on the package substrate 20. The semiconductor chip 10, 12, 14, 16 or 18 may be a semiconductor chip described with reference to FIGS. 1 to 12. The semiconductor chip 10, 12, 14, 16 or 18 may be disposed on the package substrate 20 in a face-down form. For example, the chip pads 310 of the semiconductor chip 10, 12, 14, 16 or 18 may face the package substrate 20.

The semiconductor chip 10, 12, 14, 16 or 18 may be mounted on the package substrate 20. For example, the semiconductor chip 10, 12, 14, 16 or 18 may be mounted on the package substrate 20 in a flip chip manner. Chip terminals 350 may be provided on the chip pads 310 of the semiconductor chip 10, 12, 14, 16 or 18. The chip terminals 350 may connect the chip pads 310 of the semiconductor chip 10, 12, 14, 16 or 18 and the upper substrate pads of the package substrate 20. According to some example embodiments, the semiconductor chip 10, 12, 14, 16 or 18 may be mounted on the package substrate 20 in a wire bonding manner.

A molding layer 30 may be provided on the package substrate 20. The molding layer 30 may cover the semiconductor chip 10, 12, 14, 16 or 18 on the upper surface of the package substrate 20. The molding layer 30 may include an insulating polymer material such as an epoxy molding compound (EMC). However, example embodiments are not limited thereto.

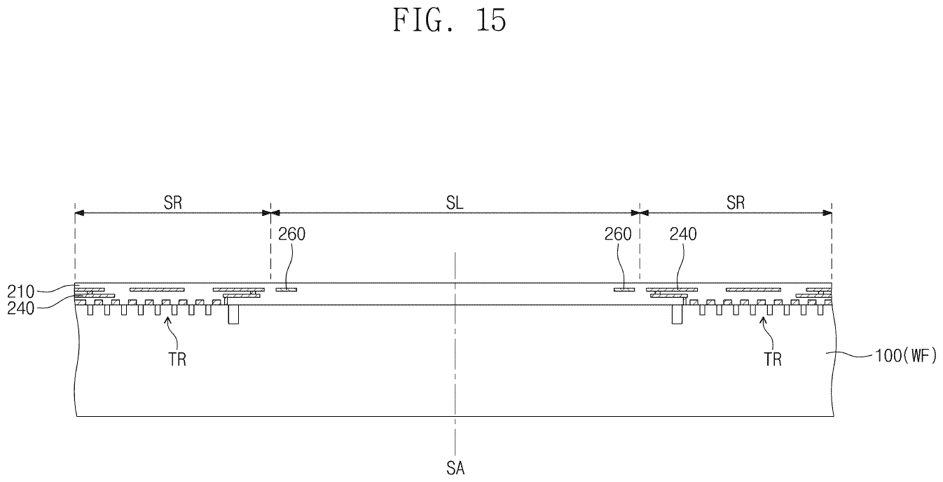

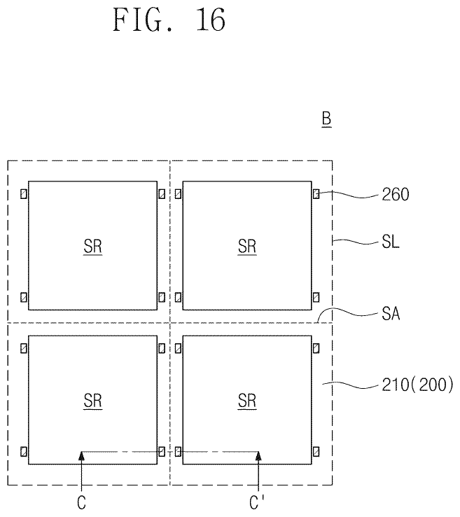

FIGS. 14 to 24 are cross-sectional and plan views for describing a method for manufacturing the semiconductor package according to some example embodiments of the inventive concepts. FIG. 14 is a plan view illustrating a semiconductor wafer for manufacturing the semiconductor package according to some example embodiments of the inventive concepts. FIGS. 15, 17, 19, 21, 23 and 24 are cross-sectional views for describing the method for manufacturing the semiconductor package according to some example embodiments of the inventive concepts. FIGS. 16, 18, 20, and 22 are plan views for describing the method for manufacturing the semiconductor package according to some example embodiments of the inventive concepts, and may correspond to region B of FIG. 14. FIGS. 15, 17, 19 and 21 may respectively correspond to cross-sections taken along line C-C′ of FIGS. 16, 18, 20, 22.

Referring to FIGS. 14 to 16, a semiconductor wafer WF may be provided. The semiconductor wafer WF may have a plurality of regions on which semiconductor chips are formed. For example, the semiconductor wafer WF may have a plurality of device regions SR. The device regions SR may be spaced apart from each other with a scribe lane region SL on which a sawing process is performed in a process to be described later therebetween. That is, the scribe lane region SL may define the device regions SR, on which the semiconductor chips are formed, on the semiconductor wafer WF. The semiconductor wafer WF may be the semiconductor substrate 100 on which the transistors TR in the semiconductor chips are formed.

The transistors TR may be formed by performing a typical process on the upper surface of the semiconductor substrate 100. The transistors TR may be formed on the device regions SR.

The first interlayer insulating layer 210 and the wiring patterns 240 may be formed on the semiconductor substrate 100. For example, the first interlayer insulating layer 210 and the wiring patterns 240 may be formed by repeatedly performing depositing an insulating layer on the upper surface of the semiconductor substrate 100, patterning the insulating layer, depositing a conductive layer, and patterning the conductive layer. However, a method for forming the first interlayer insulating layer 210 and the wiring patterns 240 in the inventive concepts are not limited thereto, and the first interlayer insulating layer 210 and the wiring patterns 240 may be formed through a typical method. The first interlayer insulating layer 210 may cover the semiconductor substrate 100 on the device regions SR and the scribe lane region SL. During a process of forming the wiring patterns 240, the align key 260 located in the first interlayer insulating layer 210 on the scribe lane region SL may be formed together.

Referring to FIGS. 14, 17 and 18, the dielectric layer 220 may be formed on the first interlayer insulating layer 210. For example, the dielectric layer 220 may be formed by depositing or applying a dielectric layer on the upper surface of the first interlayer insulating layer 210. A curing process may be additionally performed on the dielectric layer as needed. However, a method for forming the dielectric layer 220 in the inventive concepts are not limited thereto, and the dielectric layer 220 may be formed through a typical method. The dielectric layer 220 may cover the first interlayer insulating layer 210 on the device regions SR and the scribe lane region SL.

The second interlayer insulating layer 230 and wiring patterns may be formed on the dielectric layer 220. For example, the second interlayer insulating layer 230 and the wiring patterns may be formed by repeatedly performing depositing an insulating layer on the upper surface of the dielectric layer 220, patterning the insulating layer, depositing a conductive layer, and patterning the conductive layer. However, a method for forming the second interlayer insulating layer 230 and the wiring patterns in the inventive concepts are not limited thereto, and the second interlayer insulating layer 230 and the wiring patterns may be formed through a typical method. The second interlayer insulating layer 230 may cover the dielectric layer 220 on the device regions SR and the scribe lane region SL. During a process of forming the wiring patterns, the align key 260 located in the second interlayer insulating layer 230 on the scribe lane region SL may be formed together.

The first interlayer insulating layer 210, the dielectric layer 220 and the second interlayer insulating layer 230 may constitute the wiring layer 200.

Referring to FIGS. 14, 19, and 20, the passivation layer 300 may be formed on the wiring layer 200. For example, the passivation layer 300 may be formed by depositing or applying an insulating layer on the upper surface of the second interlayer insulating layer 230. A curing process may be additionally performed on the insulating layer as needed. However, a method for forming the passivation layer 300 in the inventive concepts are not limited thereto, and the passivation layer 300 may be formed through a typical method. The passivation layer 300 may cover the second interlayer insulating layer 230 on the device regions SR and the scribe lane region SL.

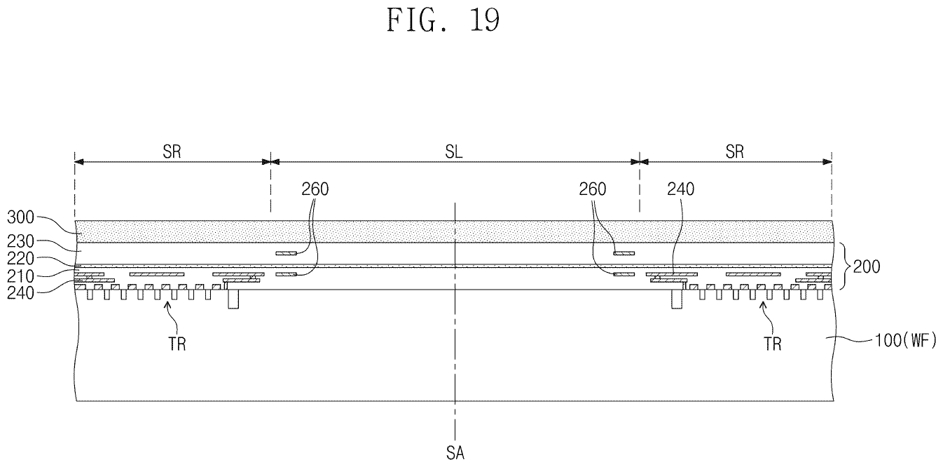

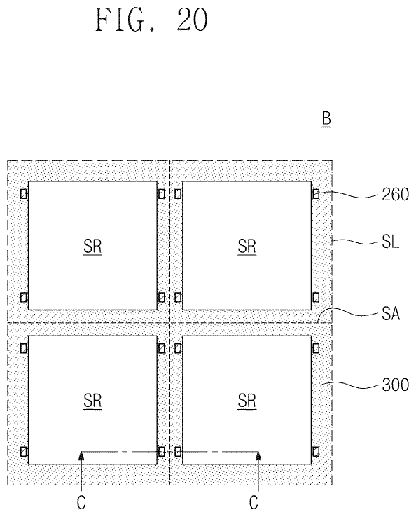

According to some example embodiments, before the passivation layer 300 is formed, an additional insulating layer may be formed on the second interlayer insulating layer 230. For example, the additional insulating layer may be formed by depositing an insulating layer on the upper surface of the second interlayer insulating layer 230. However, a method for forming the additional insulating layer in the inventive concepts are not limited thereto, and the additional insulating layer may be formed through a typical method. The additional insulating layer may cover the second interlayer insulating layer 230 on the device regions SR and the scribe lane region SL. The additional insulating layer may be formed so as to conformally cover the upper surface of the second interlayer insulating layer 230. The additional insulating layer may not be formed as needed. Hereinafter, descriptions will be made in reference to some example embodiments of FIGS. 19 and 20.

Referring to FIGS. 14, 21 and 22, the trenches T may be formed by patterning the passivation layer 300 and the wiring layer 200. For example, an etching process may be performed on the passivation layer 300. During the etching process, the trenches T may penetrate the passivation layer 300, the second interlayer insulating layer 230 and the dielectric layer 220 to extend into the first interlayer insulating layer 210. Alternatively, during the etching process, the trenches T may penetrate the passivation layer 300, the second interlayer insulating layer 230, the dielectric layer 220 and the first interlayer insulating layer 210 to extend into the semiconductor substrate 100.

The trenches T may be formed so as to penetrate the align keys 260. The etching process may include a laser grooving process. Accordingly, etching the align keys 260 composed of metal may be performed during the etching process. A focusing height of the laser grooving process may be greater than a distance from the upper surface of the passivation layer 300 to the upper surface of the first interlayer insulating layer 210, or a distance from the upper surface of the passivation layer 300 to the upper surface of the semiconductor substrate 100. For example, during the laser grooving process, the first interlayer insulating layer 210 or the semiconductor substrate 100 may be irradiated with a laser beam so as to focus thereon.

The laser grooving process may be performed along the scribe lane region SL. Each of the trenches T may be formed so as to surround one device region SR. A distance between the trenches T adjacent to each other, that is, the trenches T, surrounding the device regions SR, adjacent to each other may be about 10 μm to about 30 μm.

According to some example embodiments, in a plan view, the trenches T may be formed so as to have a lattice shape. For example, the trenches T may be formed in a form of a plurality of lines extending along the scribe lane region SL.

According to some example embodiments of the inventive concepts, the trenches T may be formed by using the laser grooving process. The trenches T may be formed so as to penetrate the align keys 260 formed in the wiring layer 200. Accordingly, each of the trenches T may be formed so as to completely surround one device region SR, and the dielectric layer 220 on the scribe lane region SL and the dielectric layer 220 on the device region SR may be separated from each other without a connection part therebetween. That is, the trenches T may suppress a damage or a fracture from propagating toward the device region SR in a process (for example, the sawing process, or the like) to be described later, and the method for manufacturing the semiconductor package with fewer defects may be provided.

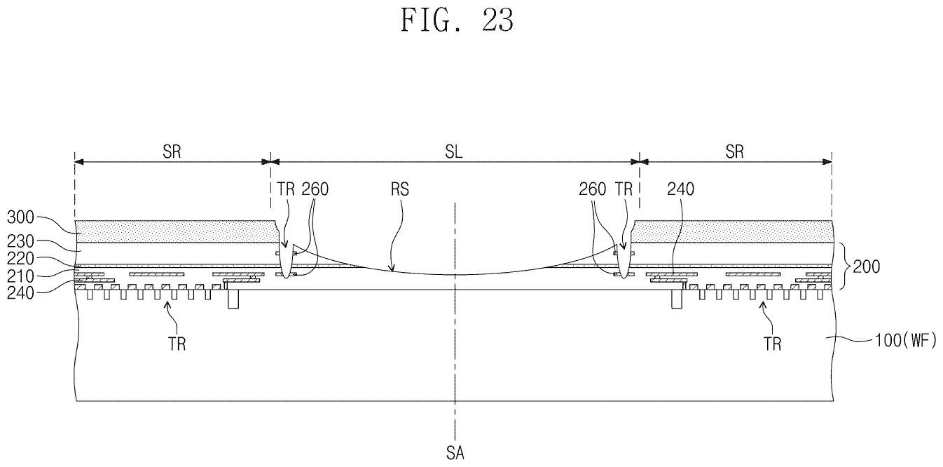

According to some example embodiments, as illustrated in FIG. 23, before the trenches T are formed, the recess region RS may be formed on the passivation layer 300. For example, a mask pattern may be formed on the passivation layer 300, and then an etching process may be performed using the mask pattern as an etching mask. During the etching process, the recess region RS may penetrate the passivation layer 300 to extend into the wiring layer 200. More specifically, the bottom surface of the recess region RS may expose the first interlayer insulating layer 210. The recess region RS may be formed on the scribe lane region SL. More specifically, the recess region RS may be located on a sawing line SA set in the scribe lane region SL. Here, the sawing line SA may be an arbitrary line on which the sawing process is performed in a process to be described later. The sawing line SA may cross a region between the device regions SR. The recess region RS may be formed after forming the trenches T as needed.

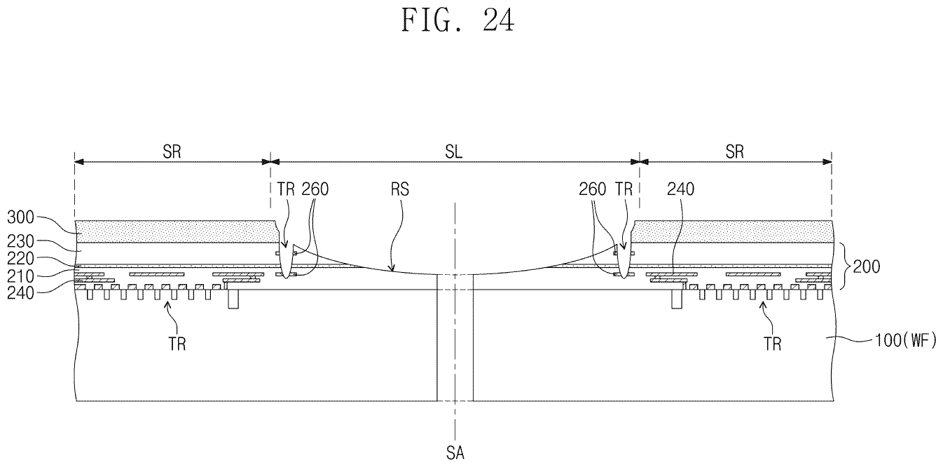

Referring to FIGS. 14 and 24, a singulation process may be performed. For example, a plurality of semiconductor chips may be separated from each other by performing a cutting process along the sawing line SA of the semiconductor substrate 100.

According to some example embodiments of the inventive concepts, the first interlayer insulating layer 210 may include oxide of a semiconductor material that constitutes the semiconductor substrate 100. Accordingly, the semiconductor substrate 100 and the first interlayer insulating layer 210 located on the sawing line SA may have similar crystallinity. The passivation layer 300 and the dielectric layer 220 having different crystallinity from the semiconductor substrate 100 may be removed on the sawing line SA on which the sawing process is performed. Accordingly, the semiconductor substrate 100 and material layers disposed thereon may be more easily cut during the sawing process.

Since in a semiconductor package according to some example embodiments of the inventive concepts, a trench is provided so as to entirely surround a device region, a portion of a dielectric layer located on the device region and another portion of the dielectric layer located outside a semiconductor chip may be separated without a connection part. That is, the trench may suppress a damage or a fracture from propagating from an outside of the semiconductor chip toward the device region, and the semiconductor package with more improved structural stability and/or reliability may be provided.

In addition, parts, in contact with the trench, of a first interlayer insulating layer and a second interlayer insulating layer may be provided having a more crack-resistant amorphous structure. That is, the semiconductor package with improved structural stability and/or reliability may be provided.

In a method for manufacturing the semiconductor package according to some example embodiments of the inventive concepts, trenches may be formed so as to penetrate align keys formed in a wiring layer by using a laser grooving process. Accordingly, each of the trenches may be formed so as to completely surround one device region. That is, the trenches may suppress the damage or the fracture from propagating toward the device region in a subsequent process such as a sawing process, and the method for manufacturing the semiconductor package with fewer defects may be provided.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Although example embodiments of the present invention have been described, it is understood that the present invention should not be limited to these example embodiments but various changes and modifications can be made by one ordinary skilled in the art within the spirit and scope of the present invention as hereinafter claimed. Therefore, it should be understood that the example embodiments described above are not intended to be limiting.

What is claimed is:

1. A semiconductor package comprising:
a semiconductor substrate comprising
a device region on an upper surface of the semiconductor substrate, and
a dummy region surrounding the device region;
an integrated circuit on the upper surface of the semiconductor substrate in the device region;
a first interlayer insulating layer covering the integrated circuit on the upper surface of the semiconductor substrate;
a second interlayer insulating layer on the first interlayer insulating layer;
a dielectric layer between the first interlayer insulating layer and the second interlayer insulating layer;
a trench vertically penetrating the second interlayer insulating layer and the dielectric layer in the dummy region; and
a passivation layer on the second interlayer insulating layer,
wherein the trench surrounds the device region along the dummy region.

2. The semiconductor package of claim 1, wherein
a lowermost end of the trench is at a level lower than an upper surface of the first interlayer insulating layer and at a level higher than a lower surface of the first interlayer insulating layer, or
the lowermost end of the trench is at a level lower than the upper surface of the semiconductor substrate and at a level higher than a lower surface of the semiconductor substrate.

3. The semiconductor package of claim 1, wherein the trench has a cross-section having a form of U shape or V shape.

4. The semiconductor package of claim 1, wherein, in a plan view, the trench has a form of a closed shape surrounding the device region.

5. The semiconductor package of claim 1, wherein
the dielectric layer has a first dielectric layer and a second dielectric layer separated from each other by the trench,
the first dielectric layer is in the device region, and
the second dielectric layer is in the dummy region.

6. The semiconductor package of claim 1, wherein a distance from a side surface of the semiconductor substrate to the trench is 3 μm to 20 μm.

7. The semiconductor package of claim 1, wherein the trench has a width of 3 μm to 20 μm.

8. The semiconductor package of claim 1, further comprising:
an align key on the semiconductor substrate in the dummy region,
wherein the align key is between a lower surface of the first interlayer insulating layer and an upper surface of the second interlayer insulating layer, and
the trench vertically penetrates the align key.

9. The semiconductor package of claim 1, further comprising:
an additional insulating layer between the second interlayer insulating layer and the passivation layer,
wherein the additional insulating layer conformally covers an upper surface of the second interlayer insulating layer.

10. The semiconductor package of claim 1, wherein the trench vertically penetrates the passivation layer, the second interlayer insulating layer, and the dielectric layer.

11. The semiconductor package of claim 1, wherein
the first interlayer insulating layer comprises
a first part adjacent to the trench, and
a second part spaced apart from the trench by the first part,
the first part and the second part are composed of a same material,
the first part has an amorphous structure, and
the second part has a crystalline structure.

12. A semiconductor package comprising:
a semiconductor substrate comprising
a device region on an upper surface of the semiconductor substrate, and
a dummy region surrounding the device region;
an integrated circuit on the upper surface of the semiconductor substrate in the device region;
a first interlayer insulating layer covering the integrated circuit on the upper surface of the semiconductor substrate;
a second interlayer insulating layer on the first interlayer insulating layer;
a dielectric layer between the first interlayer insulating layer and the second interlayer insulating layer;
a trench vertically penetrating the second interlayer insulating layer and the dielectric layer in the dummy region; and
a passivation layer on the second interlayer insulating layer,
wherein the first interlayer insulating layer comprises
a first part adjacent to the trench; and
a second part spaced apart from the trench by the first part,
the first part and the second part are composed of a same material,
the first part has an amorphous structure, and
the second part has a crystalline structure.

13. The semiconductor package of claim 12, wherein, in a plan view, the trench has a form of a closed shape surrounding the device region.

14. The semiconductor package of claim 12, wherein
a lowermost end of the trench is at a level lower than an upper surface of the first interlayer insulating layer and at a level higher than a lower surface of the first interlayer insulating layer, or
the lowermost end of the trench is at a level lower than the upper surface of the semiconductor substrate and at a level higher than a lower surface of the semiconductor substrate.

15. The semiconductor package of claim 12, wherein the trench has a cross-section having a form of U shape or V shape.

16. The semiconductor package of claim 12, wherein a distance from a side surface of the semiconductor substrate to the trench is 3 μm to 20 μm.

17. The semiconductor package of claim 12, wherein
the dielectric layer has a first dielectric layer and a second dielectric layer separated from each other by the trench,
the first dielectric layer in the device region, and
the second dielectric layer is located in the dummy region.

18. The semiconductor package of claim 12, further comprising:
an align key on the semiconductor substrate in the dummy region,
wherein the align key is between a lower surface of the first interlayer insulating layer and an upper surface of the second interlayer insulating layer, and
the trench vertically penetrates the align key.

19. The semiconductor package of claim 12, wherein the trench vertically penetrates the passivation layer, the second interlayer insulating layer, and the dielectric layer.

20. A semiconductor package comprising:
a package substrate; and
a semiconductor chip mounted on the package substrate,
wherein the semiconductor chip comprises
a semiconductor substrate comprising
a device region on an upper surface of the semiconductor substrate, and
a dummy region surrounding the device region,
an integrated circuit on the upper surface of the semiconductor substrate in the device region,
a first interlayer insulating layer covering the integrated circuit on the upper surface of the semiconductor substrate,
a second interlayer insulating layer on the first interlayer insulating layer,
a dielectric layer between the first interlayer insulating layer and the second interlayer insulating layer,
a passivation layer on the second interlayer insulating layer,
an align key provided onto the semiconductor substrate in the dummy region, and
a trench vertically penetrating the passivation layer, the second interlayer insulating layer and the dielectric layer in the dummy region,
the align key is between a lower surface of the first interlayer insulating layer and an upper surface of the second interlayer insulating layer,
a lowermost end of the trench is at a level lower than an upper surface of the first interlayer insulating layer,
the trench, at least partially, vertically penetrates the align key, and
the trench horizontally crosses the align key.
